(19) United States
(12) Patent Application Publication
(10) Pub. No.: US 2004/0152215 A1
(43) Pub. Date: Aug. 5, 2004

(54) Method of making a haze free PZT film

(76) Inventors: Sanjeev Aggarwal, Plano, TX (US); Kelly J. Taylor, Allen, TX (US); Angelica Thomas, Allen, TX (US)

Correspondence Address: TEXAS INSTRUMENTS INCORPORATED, P O BOX 655474, M/S 3999, DALLAS, TX, 75265

(21) Appl. No.: 10/356,114

(22) Filed: Jan. 30, 2003

(51) Int. Cl. H01L 21/00; H01L 21/8242

(52) U.S. Cl. 438/3; 438/240

(57) ABSTRACT

An embodiment of the invention is a method of fabricating a haze free, phase pure, PZT film, 3, where a vacuum, an inert gas, or a mixture of an inert and oxidizer gas is used in the preheat step, 208, prior to the deposition, 210, of the PZT film, 3.

### BACKGROUND OF THE INVENTION

During the deposition of the PZT capacitor dielectric layer of a ferroelectric capacitor, PbO is deposited on the walls of the deposition chamber. Thereafter, the PbO deposits will dislodge from the deposition chamber walls and settle onto any semiconductor wafer contained in the chamber. This deposition of PbO on the wafer causes the PZT layer to have haze (roughness). The haze is undesirable and degrades the properties of the ferroelectric capacitor. This invention concerns the fabrication of lead rich PZT films that are haze free.

### CROSS-REFERENCE To RELATED APPLICATIONS

This application is related to application Serial Number ______ (Attorney Docket Number TI-35729) filed on the same date as this application and entitled “Method of Making a Haze Free, Lead Rich PZT Film”. With its mention in this section, this patent application is not admitted to be prior art with respect to the present invention.

### BRIEF DESCRIPTION OF THE DRAWINGS

FIG. 1 is a cross-section view of a semiconductor wafer having a PZT film.

FIG. 2 is a flow diagram illustrating the process flow of the present invention.

FIG. 3 is a cross-section view of a partially fabricated memory device that is fabricated in accordance with the present invention.

FIG. 4 is a cross-section view of a portion of a MOCVD chamber.

### DETAILED DESCRIPTION OF THE INVENTION

The present invention is described with reference to the attached figures, wherein similar reference numerals are used throughout the figures to designate like or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention.

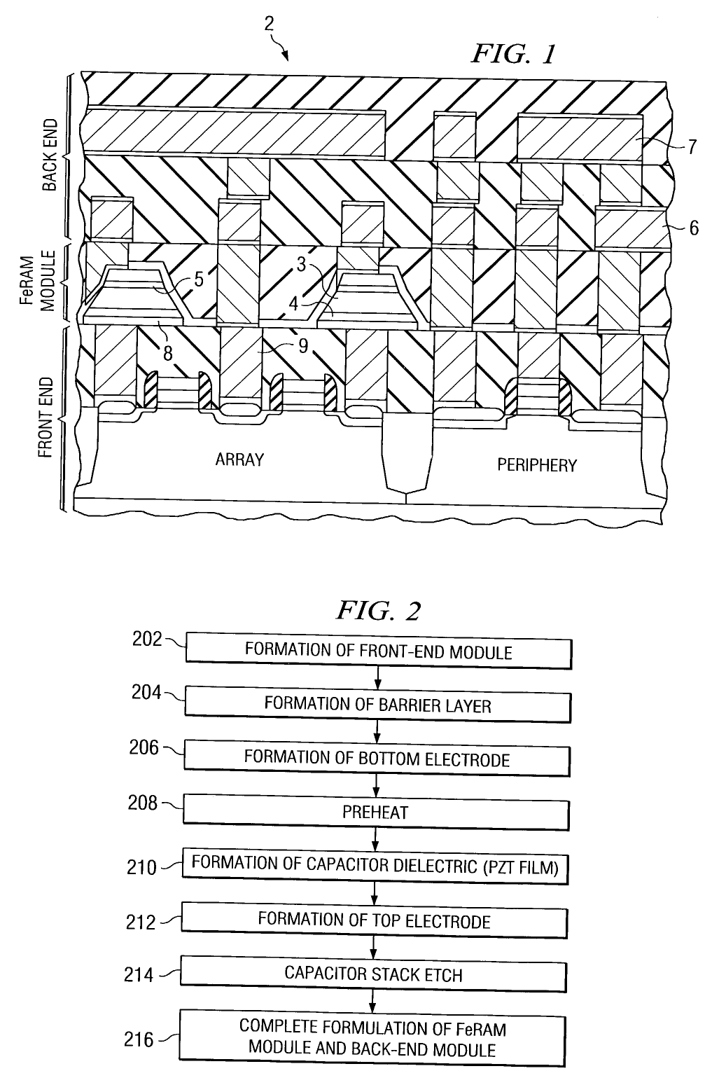

Referring to the drawings, FIG. 1 depicts a cross-section of a portion of a semiconductor wafer, 2, having a haze free, phase pure, PZT film in accordance with the invention. More specifically, FIG. 1 shows a partially fabricated FeRAM (ferroelectric memory) array and periphery (which includes most of the rest of the logic chip). In the best mode application the FeRAM module is located between the standard logic front end and back end. The transistor logic is contained in the front-end portion of the wafer (closest to the substrate). The memory module contains non-volatile memory. The device's interconnects and metal lines—used to move electrical signals and power throughout the device—are contained in the back end portion of the wafer. Other than the best mode process of forming the PZT film located in the FeRAM module (described herein), the processing steps for creating the ferroelectric memory device is described in commonly assigned patent/patent application having Ser. No. 09/702,985 (TI Docket number TI-29970, filed Oct. 31, 2000), incorporated herein by reference, and not admitted to be prior art with respect to the present invention by its mention in this section.

The single capacitor memory cell (referred to as a “1T/1C” or “1C” memory cell) has one transistor and one storage capacitor. The bottom electrode of the storage capacitor is connected to the drain of the transistor. In this example application, shown in FIG. 1, the FeRAM memory module is located between the front-end module and the back end module. However, other locations for the FeRAM memory module are within the scope of this invention. For example, the FeRAM module may be placed over the first level of metallization, 6, or near the end of the back end module, 7. Furthermore, it is within the scope of this invention to have a FeRAM module containing a dual capacitor memory cell (comprising two transistors and two ferroelectric capacitors) instead of a single capacitor memory cell.

The FeRAM memory module contains numerous FeRAM memory cells. The ferroelectric capacitor contained within the ferroelectric memory cell is comprised of ferroelectric material, such as lead zirconate titanate (called “PZT” based on its chemical formula: Pb(Zr, Ti)O₃) that functions as a capacitor dielectric, 3, situated between a bottom electrode, 4, and a top electrode, 5. In the best mode application, the bottom electrode, 4, is comprised of iridium, iridium oxide, or a stack thereof. Similarly, the top electrode, 5, is comprised of iridium, iridium oxide, or a stack thereof.

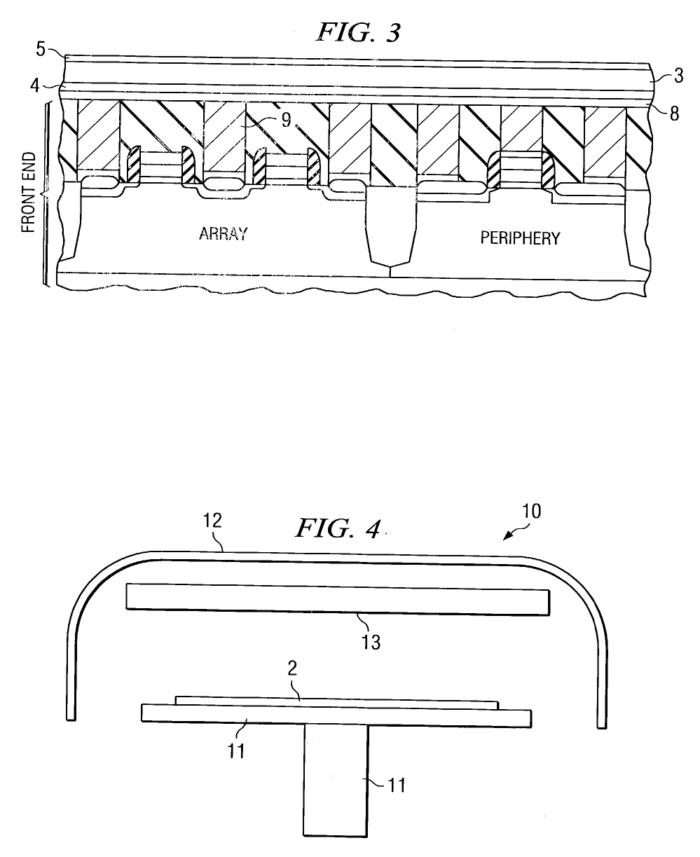

Referring now to FIGS. 2 and 3, after the formulation of the front-end module (step 202), there is a barrier layer, 8, formed (step 204) over the contacts, 9 (which are connected to the substrate and gates contained in the front-end module). The conductive barrier, 8, may be formed by a reactive sputter deposition of TiAlN; however, other deposition techniques or barrier materials may be used. For example, instead of using TiAlN as the barrier material, either TiAlON, TiN, or a stack having any combination of these three materials may be used.

Next, the bottom electrode, 4, is formed (step 206) on the barrier layer, 8. The bottom electrode, 4, is formed by sputter deposition of Ir (using Ar as the inert gas, but other inert gases may be used). Conversely, the bottom electrode, 4, may be formed by reactive sputter deposition of IrOₓ (using (Ar+O₂) as the gas mixture, but inert gases other than Ar may be used in the mixture). However, other deposition techniques may be used to form the bottom electrode, 4, such as chemical vapor deposition. Moreover, other materials may be used for the bottom electrode, such as Pt, Pd, PdOx, Au, Ru, RuOx, Rh, or RhOx.

Referring to FIG. 4, the semiconductor wafer, 2, is now subjected to a preheat step (step 208) prior to the deposition of the capacitor dielectric PZT film, 3. In the example application, the PZT film, 3, is formed by a deposition technique called metal organic chemical vapor deposition (“MOCVD”). Therefore, in the example application the preheat treatment of the semiconductor wafer, 2, is also performed in the MOCVD chamber. As an example, the MOCVD may be performed using a machine such as the Centura manufactured by AMAT (Applied Materials). However other deposition techniques may be used without departing from the spirit of this invention.

FIG. 4 shows a cross-section of a portion of a MOCVD chamber, 10. During the preheat step, the semiconductor wafer, 2, sits on a heater, 11, within the chamber walls, 12 of the MOCVD chamber, 10. In accordance with the invention, an inert gas is introduced into the chamber through the showerhead, 13, during the preheat step. In the best mode application, a combination of Ar and O₂ (whereby Ar comprises at least 20% of the total gas flow) is introduced into the MOCVD chamber, 10., for approximately 60 seconds. However, the use of other inert gases such as He, N₂, or only Ar, is within the scope of this invention. Furthermore, it is within the scope of this invention not to use any gas during the preheat step, rather the preheat step is performed in a vacuum in the MOCVD chamber, 10.

Referring again to FIG. 3, the stoichiometric capacitor dielectric, 3, is formed using the MOCVD technique. More specifically, PbO+ZrO₂+TiO₂ is introduced into the MOCVD chamber, 10, creating a Pb(ZrTi)O₃ film, 3, on the semiconductor wafer, 2, plus PbO which sticks to the chamber walls or is out-gassed by the chamber. Because of the preheat step that was performed in accordance with the invention hereinabove, a haze free, phase pure PZT film, 3, is now formed (step 210) on the bottom electrode, 4.

The PZT film is preferably less than 150 nm thick (most preferably the PZT film is less than 70 nm thick). Furthermore, PZT film, 3, is lead rich, having an atomic concentration of Pb of greater than 1.00 and less than or equal to 1.02 (i.e. Pb_{1.02} (Zr,Ti)O₃); which is close to 100% lead composition of the film. In an example application, the PZT film, 3, is deposited at temperatures between 450-650° C. and at pressures between 2-8 Torr.

Next, the top electrode, 5, is formed (step 212) on the capacitor dielectric, 3. In the example application, the top electrode, 5, is formed by sputter deposition of Ir (using Ar as the inert gas, but other inert gases may be used). Conversely, the top electrode, 5, may be formed by reactive sputter deposition of IrOₓ (using (Ar+O₂) as the gas mixture, but inert gases other than Ar may be used in the mixture). However, other deposition techniques may be used to form the top electrode, 5, such as chemical vapor deposition. Furthermore, other materials may be used for the top electrode, such as Pt, Pd, PdOx, Au, Ru, RuOx, Rh, or RhOx.

The entire capacitor stack (comprised of barrier, 8, bottom electrode, 4, capacitor dielectric, 3, and tope electrode, 5) is patterned, etched, and cleaned to form (step 214) the final ferroelectric capacitor structure. The formation (step 216) of the final device structure continues, including the completion of the FeRAM module and the back-end module.

By performing the preheat step in accordance with the present invention, the stoichiometric PZT film that forms the capacitor dielectric, 3, has desirable endurance, durability, and reliability. Furthermore the haze free, phase pure PZT film, 3, formed using the preheat step of the present invention will operate at a lower operating voltage and therefore reduce the power consumption of electronic devices.

Various modifications to the invention as described above are within the scope of the claimed invention. As an example, the instant invention can be used to fabricate standalone FeRAM devices or FeRAM devices integrated into a semiconductor chip that has many other device functions than those described herein. In addition, instead of forming the bottom electrode, 4, on the barrier layer, 8, the bottom electrode, 4, may be formed directly on the front-end module. Although this invention description focuses on the formation of planar capacitors, a three-dimensional capacitor using a post or cup structure can be fabricated with the same inventive process. Furthermore, the preheat step and deposition of the capacitor dielectric, 3, may be accomplished by a technique other than MOCVD (i.e. sputtering, MOD, or sol-gel). Moreover, the invention is applicable to semiconductor wafers having different well and substrate technologies, transistor configurations, and metal connector materials or configurations. Furthermore, the invention is applicable to other semiconductor technologies such as BiCMOS, bipolar, SOI, strained silicon, pyToelectric sensors, optoelectronic devices, microelectrical mechanical system (“MEMS”), or SiGe.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method of fabricating a PZT film on a semiconductor wafer comprising:
forming a front-end structure over a semiconductor substrate;
forming a bottom electrode over said front-end structure;
preheating said semiconductor wafer; and
forming a PZT film over said bottom electrode;
wherein said preheating step comprises heating said semiconductor wafer in an ambient comprised of a mixture of an inert gas and an oxidizer gas.

2. The method of claim 1 wherein said inert gas is He.

3. The method of claim 1 wherein said inert gas is Ar.

4. The method of claim 1 wherein said inert gas is N.

5. The method of claim 1 wherein said oxidizer gas is O₂.

6. The method of claim 1 wherein said oxidizer gas is N₂O.

7. The method of claim 1 wherein said oxidizer gas is O₃.

8. The method of claim 3, wherein Ar comprises at least 20% of the flow of said inert/oxidizer gas mixture.

9. The method of claim 1 wherein said PZT film contains at least 2% excess Pb from the stoichiometric composition of Pb_{1.0}(Zr,Ti)_{1.0}O₃.

10. The method of claim 1 wherein said PZT film is PbZrO₃.

11. The method of claim 1 wherein said PZT film is PbTi_{1.0}O₃.

12. The method of claim 1 wherein said PZT film is a solid solution of the component end members PbZrO₃ and PbTiO₃.

13. The method of claim 1 wherein said PZT film is doped up to 5% with either La or Nb.

14. The method of claim 1 wherein a ferroelectric capacitor is fabricated by further forming a top electrode over said PZT film.

15. The method of claim 1 wherein said bottom electrode is comprised of a material selected from the group consisting of: Ir, IrOₓ, or a stack thereof.

16. The method of claim 14 wherein said top electrode is comprised of a material selected from the group consisting of: Ir, IrOₓ, or a stack thereof.

17. A method of fabricating a PZT film on a semiconductor wafer comprising:
forming a front-end structure over a semiconductor substrate;
forming a bottom electrode over said front-end structure;
preheating said semiconductor wafer; and
forming a PZT film over said bottom electrode;
wherein said preheating step comprises heating said semiconductor wafer in an inert gas.

18. The method of claim 17 wherein said inert gas is He.

19. The method of claim 17 wherein said inert gas is Ar.

20. The method of claim 17 wherein said inert gas is N₂.

21. The method of claim 17 wherein said PZT film contains at least 2% excess Pb from the stoichiometric composition of Pb_{1.0}(Zr,Ti)_{1.0}O₃.

22. The method of claim 17 wherein said PZT film is PbZrO₃.

23. The method of claim 17 wherein said PZT film is PbTiO₃.

24. The method of claim 17 wherein said PZT film is a solid solution of the component end members PbZrO₃ and PbTiO₃.

25. The method of claim 17 wherein said PZT film is doped up to 5% with either La or Nb.

26. The method of claim 17 wherein a ferroelectric capacitor is fabricated by further forming a top electrode over said PZT film.

27. The method of claim 17 wherein said bottom electrode is comprised of a material selected from the group consisting of: Ir, IrOₓ, or a stack thereof.

28. The method of claim 26 wherein said top electrode is comprised of a material selected from the group consisting of: Ir, IrOₓ, or a stack thereof.

29. A method of fabricating a PZT film over a semiconductor wafer comprising:
forming a front-end structure;
forming a bottom electrode over said front-end structure;
preheating said semiconductor wafer; and
forming a PZT film over said bottom electrode;
wherein said preheating step comprises heating said semiconductor wafer in a vacuum.

30. The method of claim 29 wherein said PZT film contains at least 2% excess Pb from the stoichiometric composition of Pb_{1.0}(Zr,Ti)_{1.0}O₃.

31. The method of claim 29 wherein said PZT film is PbZrO₃.

32. The method of claim 29 wherein said PZT film is PbTiO₃.

33. The method of claim 29 wherein said PZT film is a solid solution of the component end members PbZrO₃ and PbTiO₃.

34. The method of claim 29 wherein said PZT film is doped up to 5% with either La or Nb.

35. The method of claim 29 wherein a ferroelectric capacitor is fabricated by further forming a top electrode over said PZT film.

36. The method of claim 29 wherein said bottom electrode is comprised of a material selected from the group consisting of: Ir, IrOₓ, or a stack thereof.

37. The method of claim 35 wherein said top electrode is comprised of a material selected from the group consisting of: Ir, IrOₓ, or a stack thereof.

38. A method of fabricating an electronic device that includes a PZT film situated over a semiconductor substrate comprising:
forming a front-end structure over said semiconductor substrate;
forming a bottom electrode over said front-end structure;
preheating a semiconductor wafer containing said electronic device; and
forming a PZT film over said bottom electrode;
wherein said preheating step comprises heating said semiconductor wafer in an ambient comprised of a mixture of an inert gas and an oxidizer gas.

39. The method of claim 38 wherein said inert gas is He.

40. The method of claim 38 wherein said inert gas is Ar.

41. The method of claim 38 wherein said inert gas is N₂.

42. The method of claim 38 wherein said oxidizer gas is O₂.

43. The method of claim 38 wherein said oxidizer gas is O₂.

44. The method of claim 38 wherein said oxidizer gas is O₃.

45. The method of claim 40, wherein Ar comprises at least 20% of the flow of said inert/oxidizer gas mixture.

46. The method of claim 38 wherein said PZT film contains at least 2% excess Pb from the stoichiometric composition of Pb, ₀(Zr,Ti)_{1.0}O₃.

47. The method of claim 38 wherein said PZT film is PbZrO₃.

48. The method of claim 38 wherein said PZT film is PbTiO₃.

49. The method of claim 38 wherein said PZT film is a solid solution of the component end members PbZrO₃ and PbTiO₃.

50. The method of claim 38 wherein said PZT film is doped up to 5% with either La or Nb.

51. The method of claim 38 wherein a ferroelectric capacitor is fabricated by further forming a top electrode over said PZT film.

52. The method of claim 38 wherein said bottom electrode is comprised of a material selected from the group consisting of: Ir, IrOₓ, or a stack thereof.

53. The method of claim 51 wherein said top electrode is comprised of a material selected from the group consisting of: Ir, IrOₓ, or a stack thereof.

54. A method of fabricating an electronic device that includes a PZT film situated over a semiconductor substrate comprising:
forming a front-end structure;
forming a bottom electrode over said front-end structure;
preheating a semiconductor wafer containing said electronic device; and
forming a PZT film over said bottom electrode;
wherein said preheating step comprises heating said semiconductor wafer in a vacuum.

55. The method of claim 54 wherein said PZT film contains at least 2% excess Pb from the stoichiometric composition of Pb_{1.0}(Zr,Ti),_{1.0}O₃.

56. The method of claim 54 wherein said PZT film is PbZrO₃.

57. The method of claim 54 wherein said PZT film is PbTiO₃.

58. The method of claim 54 wherein said PZT film is a solid solution of the component end members PbZrO₃ and PbTiO₃.

59. The method of claim 54 wherein a ferroelectric capacitor is fabricated by further forming a top electrode over said PZT film.

60. The method of claim 54 wherein said bottom electrode is comprised of a material selected from the group consisting of: Ir, IrOₓ, or a stack thereof.

61. The method of claim 59 wherein said top electrode is comprised of a material selected from the group consisting of: Ir, IrOₓ, or a stack thereof.

62. A method of fabricating an electronic device that includes a PZT film situated over a semiconductor substrate comprising:
forming a front-end structure over a semiconductor substrate;
forming a bottom electrode over said front-end structure;
preheating said semiconductor wafer; and
forming a PZT film over said bottom electrode;
wherein said preheating step comprises heating said semiconductor wafer in an inert gas.

63. The method of claim 62 wherein said inert gas is He.

64. The method of claim 62 wherein said inert gas is Ar.

65. The method of claim 62 wherein said inert gas is N₂.

66. The method of claim 62 wherein said PZT film contains at least 2% excess Pb from the stoichiometric composition of Pb_{1.0}(Zr,Ti)_{1.0}O₃.

67. The method of claim 62 wherein said PZT film is PbZrO₃.

68. The method of claim 62 wherein said PZT film is PbTiO₃.

69. The method of claim 62 wherein said PZT film is a solid solution of the component end members PbZrO₃ and PbTiO₃.

70. The method of claim 62 wherein said PZT film is doped up to 5% with either La or Nb.

71. The method of claim 62 wherein a ferroelectric capacitor is fabricated by further forming a top electrode over said PZT film.

72. The method of claim 62 wherein said bottom electrode is comprised of a material selected from the group consisting of: Ir, IrOₓ, or a stack thereof.

73. The method of claim 71 wherein said top electrode is comprised of a material selected from the group consisting of: Ir, IrOₓ, or a stack thereof.

74. A haze free PZT film prepared in accordance with claim 1.

75. A haze free PZT film prepared in accordance with claim 17.

76. A haze free PZT film prepared in accordance with claim 29.

77. A haze free PZT film prepared in accordance with claim 38.

78. A haze free PZT film prepared in accordance with claim 54.

79. A haze free PZT film prepared in accordance with claim 62.
